(19) United States
(12) Patent Application Publication
(10) Pub. No.: US 2009/0239158 A1
(43) Pub. Date: Sep. 24, 2009

(54) Method of maintaining mask for semiconductor process

(76) Inventors: Sang-Gyun Woo, Yongin-si (KR); Dong-Hun Lee, Seoul (KR); Dong-Seok Nam, Yongin-si (KR); Hyung-Ho Ko, Hwaseong-si (KR); Seong-Yoon Kim, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/382,782

(22) Filed: Mar. 24, 2009

(30) Foreign Application Priority Data
Mar. 24, 2008 (KR) 10-2008-0026958

(51) Int. Cl. G03F 1/00

(52) U.S. Cl. 430/5

(57) ABSTRACT

A method of maintaining a mask for a semiconductor process, the method includes providing a first structure and a second structure being attached to each other via a thermosetting material, detaching the first and second structures from each other, and performing an ashing process on the first structure.

### BACKGROUND OF THE INVENTION

1. Field of the Invention

Example embodiments relate to a method of manufacturing a semiconductor. In particular, example embodiment relate to a method for maintaining a mask during a semiconductor manufacturing process using a thermosetting material.

2. Description of the Related Art

A manufacturing process for a semiconductor device may include various unit processes. For example, the unit processes may include a photolithography process, an etching process, a cleaning process, a deposition process, etc. The unit processes may be performed repeatedly to manufacture a semiconductor device, e.g., stack various patterns.

For example, a conventional photolithography process may transfer a fine pattern to be formed on a substrate, and may include exposure and development processes. In particular, the exposure process may include irradiation of ultraviolet (UV) light through a mask, e.g., a reticle, onto a photoresist on a substrate. The UV may be irradiated selectively through the mask, so a desired shape, i.e., a shape corresponding to the mask or a reverse shape of the mask, may be formed. A repeated use of the mask on the substrate may facilitate formation of the same patterns on the substrate.

A repeated use of the mask may require protection thereof from contaminants, e.g., foreign particles, to form an accurate image, e.g., a foreign particle on the mask may cause a distorted image and inaccurate patterns on the substrate. For example, the mask may require thorough cleaning and/or use of a pellicle, i.e., an optically transparent thin film transmitting light.

A conventional pellicle may be attached to the mask via an adhesive. The pellicle, however, may be damaged during repeated use of the mask, or gas (i.e., fume) may be generated by a photochemical reaction in a space between the pellicle and the mask. Accordingly, in order to avoid distorted patterns, e.g., a pattern formed by UV penetrating through gas may be distorted, the pellicle may require relatively frequent replacement. Replacement of the pellicle may require physical removal of the pellicle from the mask. However, since the pellicle is attached to the mask via the adhesive, portions of the adhesive may remain on the mask after removal of the pellicle.

Attempts have been made to remove remaining portions of the adhesive from the mask via a cleaning process, e.g., using SC1 cleaning solution. However, the cleaning process may be insufficient to remove all the remaining portions of the adhesive from the mask, thereby generating contaminants, e.g., particles, on the mask. Contaminants on the mask may damage the manufactured semiconductor, e.g., cause formation of distorted patterns, form defective conductive patterns, reduce device reliability and operability, and so forth. As frequency of replacing the pellicle increases, and as a design rule of the semiconductor device decreases, the disadvantages and shortcomings caused by contaminants on the mask may become more serious.

### SUMMARY OF THE INVENTION

Example embodiments are therefore directed to a method of maintaining a mask during a semiconductor manufacturing process, which substantially overcomes one or more of the shortcomings and disadvantages of the related art.

It is therefore a feature of an example embodiment to provide a method of maintaining a mask during a semiconductor manufacturing process, while easily attaching/detaching a pellicle therefrom.

At least one of the above and other features may be realized by providing a method of maintaining a mask for a semiconductor process, including providing a first structure and a second structure being attached each other via a thermosetting material, detaching the first and second structures, and performing an ashing process on the first structure.

In some embodiments, the first structure may be a reticle, and the second structure may be a pellicle structure.

In other embodiments, the providing the first and second structures may include providing an adhesive including the thermosetting material between the first and second structures, and attaching the first and second structures using the adhesive.

In still other embodiments, the attaching may include supplying a heat having a first temperature to the adhesive to harden the adhesive.

In even other embodiments, the detaching may include supplying a heat having a second temperature higher than the first temperature, to the adhesive.

In yet other embodiments, the heat having the second temperature may be supplied to an interface between the first structure and the adhesive.

In further embodiments, the methods may further include cleaning the first structure after the ashing process.

In still further embodiments, the methods may further include forming a metal film between the first structure and the thermosetting material.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a schematic perspective view of a method for attaching a pellicle structure to a mask according to an example embodiment; and

FIG. 2 illustrates an enlarged view of FIG. 1 to illustrate a method for detaching the pellicle structure from the mask according to an example embodiment.

### DETAILED DESCRIPTION OF THE INVENTION

Korean Patent Application No. 10-2008-0026958, filed on Mar. 24, 2008, in the Korean Intellectual Property Office, and entitled: “Method of Maintaining Mask for Semiconductor Process,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the terms “a” and “an” are open terms that may be used in conjunction with singular items or with plural items.

A method for maintaining a mask, e.g., a reticle, during a semiconductor manufacturing process using a thermosetting material will now be described according to example embodiments. The maintaining method, i.e., using method, may include methods of attaching and detaching a pellicle structure from the mask.

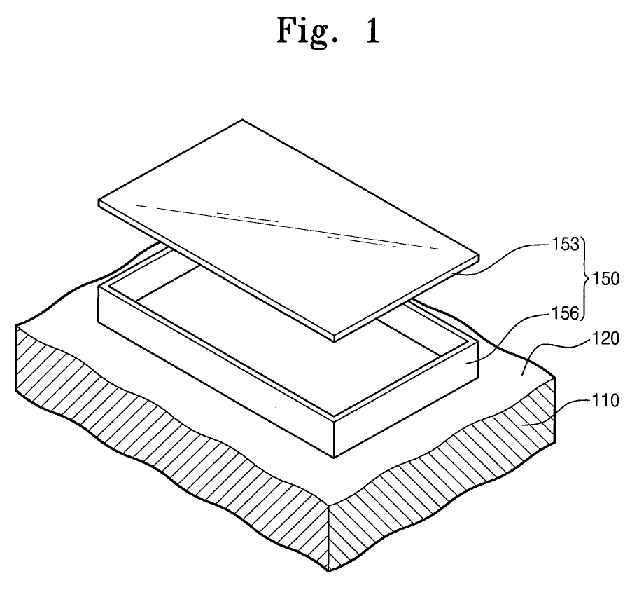

Referring to FIG. 1, a method for attaching a mask, e.g., a reticle, and a pellicle structure will now be described according to an example embodiment. Hereinafter, a mask and a reticle may be used interchangeably.

A reticle 110 may be provided for use in a semiconductor manufacturing process. The reticle 110 may be formed, e.g., of a light-transmitting material, and may have any suitable shape, e.g., a plate shape. A first surface of the reticle 110 may be coated with a metal film 120 having a predetermined pattern image, i.e., a pattern image to be formed. Accordingly, portions of the reticle 110, e.g., a light-transmitting region, may be selectively exposed through the pattern image of the metal film 120. The reticle 110 may include, e.g., quartz. The metal film 120 may include, e.g., chrome.

A pellicle structure 150 may be mounted on the first surface of the reticle 110. The pellicle structure 150 may include a pellicle 153 and a pellicle frame 156. The pellicle 153 may be attached to the pellicle frame 156. For example, the pellicle 153 may include an organic material, as an optically transparent membrane. The pellicle frame 156 may be a tetragonal frame with an open center, and may include, e.g., an anodized aluminum. The pellicle 153 may be attached to a tetragonal top surface of the pellicle frame 156. The pellicle frame 156 with the attached pellicle 153 may be mounted on the reticle 110 using a pellicle-pressing plate. The pellicle 153 may be spaced a predetermined distance from and mounted above the reticle 110 through the pellicle frame 156, i.e., the pellicle frame 156 may be positioned between the pellicle 153 and the reticle 110.

The pellicle frame 156 may be attached to the reticle 110 via an adhesive. The adhesive may be selected so heat at a first temperature may harden the adhesive and increase adhesion strength thereof, and heat at a second temperature may soften the hardened adhesive and decrease adhesion strength thereof. The second temperature may be different than the first temperature. For example, the second temperature may be higher than the first temperature. For example, the adhesive may include a thermosetting material. The adhesive may include an organic material (e.g. organic polymer). The adhesive may include a cross-linkable material by external energies (e.g. heat). The adhesive may include a removable material by an ashing process, such as organic anti-reflective coating materials and negative photo-resist materials.

In particular, a bottom surface of the pellicle frame 156, i.e., a surface opposite the top surface contacting the pellicle 153, may contact the reticle 110. The adhesive may be applied to the bottom surface of the pellicle frame 156 or to a portion of the reticle 110 where the pellicle frame 156 is mounted. For example, the adhesive may be provided through a dispenser.

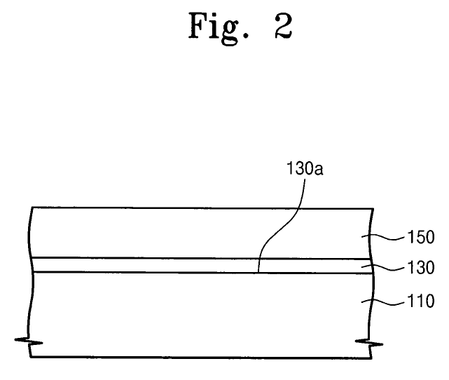

A heat having the first temperature may be applied to the adhesive between the reticle 110 and the pellicle structure 150. For example, the pellicle 110 and the reticle structure 150 may be placed in an oven at the first temperature, and the atmospheric pressure may be maintained. The adhesive may be hardened into a hardened adhesive 130 through supplying the heat having the first temperature, as illustrated in FIG. 2.

Once the adhesive hardens, the reticle 110 with the pellicle structure 150 mounted thereon may be attached to each other via the hardened adhesive 130. The reticle 110 with the pellicle structure 150 may be positioned on, e.g., a substrate, to perform an exposing process. Once the exposing process is complete, the pellicle structure 150 may be detached from the reticle 110, as will be explained in more detail below with reference to FIG. 2.

Referring to FIG. 2, a heat having the second temperature may be applied to the hardened adhesive 130 between the pellicle structure 150 and the reticle 110. For example, the pellicle structure 150 and the reticle 110 with the hardened adhesive 130 therebetween may be disposed in an oven at the second temperature, and the atmospheric pressure may be maintained. The hardened adhesive 130 may contact the reticle 110 at an interface 130a.

The heat having the second temperature may be supplied to the hardened adhesive 130 through the reticle 110, i.e., via the interface 130a, to provide the hardened adhesive 130 with increased fluidity selectively. For example, when the heat having the second temperature is supplied, the hardened adhesive 130 may be transformed to a gel-like state, and an adhesive strength of the hardened adhesive 130 may be decreased. In other words, when the hardened adhesive 130 softens due to the second temperature, the adhesion strength between the pellicle structure 150 and the reticle 110 may substantially decrease. The decreased adhesion between the pellicle structure 150 and the reticle 110 may detach, e.g., easily separate without requiring external mechanical force, the pellicle structure 150 from the reticle 110. Further, the softened adhesive may remain substantially intact, so substantially no portions of the adhesive may remain on the reticle 110, e.g., as compared to conventional adhesive.

It is noted that the second temperature and supplying time thereof may be adjusted, i.e., may have tolerances, according to suitable devices, e.g., an oven. It is further noted that the heat having the second temperature may be controlled not to be applied over the interface 130a between the reticle 110 and the hardened adhesive 130.

If adhesive residue remains on the surface of the reticle 110, an ashing process may be performed on the reticle 110. Through the ashing process, the adhesive residue may be removed from the surface of the reticle 110. Then, the reticle 110 without the pellicle structure 150 may be cleaned using a cleaning solution.

Although not shown, a substrate coated with a photoresist may be disposed under the reticle 110, and may be spaced apart from the reticle I 10. The photoresist may be a negative resist or a positive resist.

### EXAMPLES

Example 1 A reticle (MITSUI) was provided, and a pellicle structure was mounted thereon. The pellicle structure was substantially the same as the pellicle structure 150. The pellicle structure was attached to the reticle via a thermosetting adhesive as described previously with reference to FIG. 1, i.e., via heat at a first temperature. Adhesion strength between the reticle and pellicle was evaluated. Adhesive strength between the reticle and pellicle structure was evaluated via a push-pull gage, and was expressed as a pressure used for detaching the pellicle structure from the reticle. Results are shown in Table 1 below.

Next, the pellicle structure was physically detached from the reticle as described previously with reference to FIG. 2, i.e., via heat at a second temperature higher than the first temperature. After detachment, a wet cleaning process was performed on the reticle. Surface characteristics of the reticle were observed.

In particular, an organic solvent was used to rinse the reticle to collect remaining portions of adhesive residue off the reticle. The adhesive residue was dissolved in the organic solvent, and the solution including the dissolved adhesive residue was provided to a gas chromatography-mass spectrometer (GC-MS) (AGILENT Technologies Inc.) to measure a remaining amount of the adhesive on the reticle after the pellicle structures was detached. Results are shown in Table 2 below.

Comparative Example 1: Substantially same procedures were preformed as in Example 1, with the exception of using a conventional adhesive between the reticle and pellicle structure, i.e., without use of a thermosetting adhesive at the first and second temperatures.

TABLE 1

| | Example 1 | Comparative Example 1 |
|---|---|---|
| Adhesion Strength | 900 g/cm²-1100 g/cm² | 550 g/cm²-650 g/cm². |

As shown in Table 1, the adhesive strength between the pellicle structure and reticle of Example 1, i.e., attached via the adhesive of an example embodiment, was about 2 times greater than that of the adhesive strength in Comparative Example 1, i.e., attachment via a conventional adhesive.

TABLE 2

| | Example 1 | Comparative Example 1 |
|---|---|---|
| Amount of | 45 ng-60 ng | 900 ng-1100 ng |
| Adhesive | (per 1 g sample) | (per 1 g sample) |

As shown in Table 2, the adhesive amount remaining on the reticle after removal of the pellicle structure in Comparative Example 1, i.e., attached via the conventional adhesive, was about 15 times to about 20 times greater than that of the adhesive amount remaining on the reticle in Example 1.

According to the example embodiments, the adhesive strength of a pellicle structure to a reticle can be increased. Also, the pellicle structure can be easily detached from the reticle without excessively increasing the amount of a cleaning solution and a cleaning time. Further, an amount of adhesive residue remaining on the reticle after pellicle removal may be substantially reduced. Thus, the pellicle structure may be stably attached to the reticle, and surface cleanliness of the reticle may be increased, thereby reducing process costs and preventing reliability degradation of a semiconductor device due to defects.

Example embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of maintaining a mask for a semiconductor process, the method comprising:
providing a first structure and a second structure being attached to each other via a thermosetting material;
detaching the first and second structures from each other; and
performing an ashing process on the first structure.

2. The method as claimed in claim 1, wherein the first structure is a reticle, and the second structure is a pellicle structure.

3. The method as claimed in claim 1, wherein providing the first and second structures includes providing an adhesive having the thermosetting material between the first and second structures, and attaching the first and second structures using the adhesive.

4. The method as claimed in claim 3, wherein attaching the first and second structures includes supplying heat having a first temperature to the adhesive to form a hardened adhesive.

5. The method as claimed in claim 4, wherein detaching the first and second structures includes supplying heat having a second temperature to the adhesive to form a softened adhesive, the second temperature being higher than the first temperature.

6. The method as claimed in claim 5, wherein the heat having the second temperature is supplied to an interface between the first structure and the adhesive.

7. The method as claimed in claim 1, further comprising cleaning the first structure after the ashing process.

8. The method as claimed in claim 1, further comprising forming a metal film between the first structure and the thermosetting material.
